(19) United States
(12) Patent Application Publication
(10) Pub. No.: US 2024/0051817 A1
(43) Pub. Date: Feb. 15, 2024

(54) MICROELECTROMECHANICAL BUTTON DEVICE AND CORRESPONDING WATERPROOF USER INTERFACE ELEMENT

(71) Applicant: STMICROELECTRONICS S.r.l., Agrate Brianza (IT)

(72) Inventors: Federico VERCESI, Milano (IT); Gabriele GATTERE, Castronno (IT); Giorgio ALLEGATO, Monza (IT); Mikel AZPEITIA URQUIA, Milano (IT); Alessandro DANEI, Seveso (IT)

(73) Assignee: STMICROELECTRONICS S.r.l., Agrate Brianza (IT)

(21) Appl. No.: 18/363,599

(22) Filed: Aug. 1, 2023

(30) Foreign Application Priority Data
Aug. 10, 2022 (IT) 102022000017097

(51) Int. Cl. B81B 7/00; B81B 7/02; H03K 17/975

(52) U.S. Cl. CPC B81B 7/0058; B81B 7/02; H03K 17/975; H01H 2231/028; B81B 2203/04

(57) ABSTRACT

A microelectromechanical button device is provided with a detection structure having: a substrate of semiconductor material with a front surface and a rear surface; a buried electrode arranged on the substrate; a mobile electrode, arranged in a structural layer overlying the substrate and elastically suspended above the buried electrode at a separation distance so as to form a detection capacitor; and a cap coupled over the structural layer and having a first main surface facing the structural layer and a second main surface that is designed to be mechanically coupled to a deformable portion of a case of an electronic apparatus of a portable or wearable type. The cap has, on its first main surface, an actuation portion arranged over the mobile electrode and configured to cause, in the presence of a pressure applied on the second main surface, a deflection of the mobile electrode and its approach to the buried electrode, with a consequent capacitive variation of the detection capacitor, which is indicative of an actuation of the microelectromechanical button device.

### BACKGROUND

### Technical Field

The present solution relates to a microelectromechanical button device (made in MEMS—Micro-Electro-Mechanical System—technology) and to a corresponding waterproof (resistant to water or, in general, to liquids) user interface element, in particular for a portable or wearable electronic apparatus.

### Description of the Related Art

The need is known, for example in the field of portable electronic apparatuses (such as smartphones or tablets) or wearable electronic apparatuses (such as smartwatches or electronic bracelets), to provide user interface elements including physical buttons (i.e., not provided via touch-screen technology) and meeting requisites of impermeability so as to enable use of the same portable or wearable electronic apparatuses even in the presence of moisture, water, or other kinds of liquids.

In general, provision of such user interface elements is particularly complex, with dedicated assembly systems, for example including hermetic gaskets, so-called O-rings, or similar elements designed to guarantee water tightness in the coupling with an outer case or housing of the aforesaid portable or wearable electronic apparatuses and thus prevent penetration of water or other liquids into the same housing.

For instance, US 2015/0092345 A1 discloses a sealed physical button for use in a portable electronic apparatus, in particular a smartphone. This button includes a cap having a portion external to the housing of the electronic apparatus and having flange portions that interlock, inside the housing, with complementary flanges of a retainer element of a button element. The cap further comprises a downward oriented central post, proportioned and oriented to interface with the top surface of the button element. The retainer element of the button has an aperture sized and positioned for receiving the central post of the cap and rests on a shelf within the housing so as to create a sealed coupling.

Solutions of such a kind, in addition to being complex to implement, are typically subject to problems of wear and damage over time and due to the associated ageing of materials.

Other proposed solutions (see, for example, US 2013/187742 A1) envisage use of inductive elements (for example, in the form of coils) arranged within the housing of the portable or wearable electronic apparatus, at a distance from a portion of the same housing, the pressure of a user on the aforesaid portion causing a detectable variation of an inductance value of the inductive elements.

Not even the above solutions are exempt from defects, for example due to an associated energy consumption and to a general difficulty of implementation, in particular on account of the reduced dimensions available for providing the physical buttons (and the associated inductive elements) in the aforesaid portable or wearable electronic apparatuses.

### BRIEF SUMMARY

Various embodiments of the present disclosure provide a solution that will enable the problems previously highlighted to be overcome.

According to the present disclosure, a microelectromechanical button device and a corresponding user interface element for an electronic apparatus, of a portable or wearable type, are provided.

In one embodiment, a microelectromechanical button device includes a detection structure having a substrate of semiconductor material with a front surface and a rear surface; a buried electrode arranged on the substrate; a mobile electrode, arranged in a structural layer overlying the substrate and elastically suspended above the buried electrode at a separation distance so as to form a detection capacitor; and a cap coupled over the structural layer and having a first main surface facing the structural layer and a second main surface that is designed to be mechanically coupled to a deformable portion of a case of an electronic apparatus of a portable or wearable type. The cap has, on its first main surface, an actuation portion arranged over the mobile electrode and configured to cause, in the presence of a pressure applied on the second main surface, a deflection of the mobile electrode and its approach to the buried electrode, with a consequent capacitive variation of the detection capacitor, which is indicative of an actuation of the microelectromechanical button device.

### BRIEF DESCRIPTION OF THE SEVERAL VIEWS OF THE DRAWINGS

For a better understanding of the present disclosure, preferred embodiments thereof are now described, purely by way of non-limiting example, with reference to the attached drawings, wherein:

FIG. 1 is a schematic cross-sectional illustration of a portable or wearable electronic apparatus having a case that houses a microelectromechanical button device;

FIG. 2 is a schematic representation of the deformation of a deformable portion of the case of the electronic apparatus, to which the microelectromechanical button device is coupled;

FIG. 3 is a schematic cross-sectional view of the microelectromechanical button device coupled to an inner surface of the case of the portable electronic apparatus;

FIG. 4A is a more detailed schematic cross-sectional view of a detection structure of the microelectromechanical button device, according to an embodiment of the present solution;

FIG. 4B is a schematic top view of part of the detection structure of FIG. 4A;

FIGS. 5A-5G are cross-sectional views of the microelectromechanical structure of FIG. 4A, in successive steps of a corresponding manufacturing process;

FIG. 6A is a schematic cross-sectional view of a detection structure of the microelectromechanical button device, according to a further embodiment;

FIG. 6B is a schematic top view of the detection structure of FIG. 6A;

FIGS. 7A-7F are cross-sectional views of the microelectromechanical structure of FIG. 6A, in successive steps of a corresponding manufacturing process; and

FIG. 8 is a schematic cross-sectional view of a variant embodiment of the detection structure of the microelectromechanical button device.

### DETAILED DESCRIPTION

In the following description, certain details are set forth in order to provide a thorough understanding of various embodiments of devices, methods and articles. However, one of skill in the art will understand that other embodiments may be practiced without these details. In other instances, well-known structures and methods associated with, for example, image sensors, semiconductor fabrication processes, etc., have not been shown or described in detail in some figures to avoid unnecessarily obscuring descriptions of the embodiments.

Unless the context requires otherwise, throughout the specification and claims which follow, the word “comprise” and variations thereof, such as “comprising,” and “comprises,” are to be construed in an open, inclusive sense, that is, as “including, but not limited to.”

Reference throughout this specification to “one embodiment,” or “an embodiment” means that a particular feature, structure or characteristic described in connection with the embodiment is included in at least one embodiment. Thus, the appearances of the phrases “in one embodiment,” or “in an embodiment” in various places throughout this specification are not necessarily referring to the same embodiment, or to all embodiments. Furthermore, the particular features, structures, or characteristics may be combined in any suitable manner in one or more embodiments to obtain further embodiments.

The headings are provided for convenience, and do not interpret the scope or meaning of this disclosure or the claims.

The sizes and relative positions of elements in the drawings are not necessarily drawn to scale. For example, the shapes of various elements and angles may not be drawn to scale, and some of these elements may be enlarged and positioned to improve drawing legibility. Further, the particular shapes of the elements as drawn are not necessarily intended to convey any information regarding the actual shape of particular elements, and have been selected solely for ease of recognition in the drawings. Geometric references are not intended to refer to ideal embodiments. For example, a reference to square-shaped does not mean that an element has a geometrically perfect square shape.

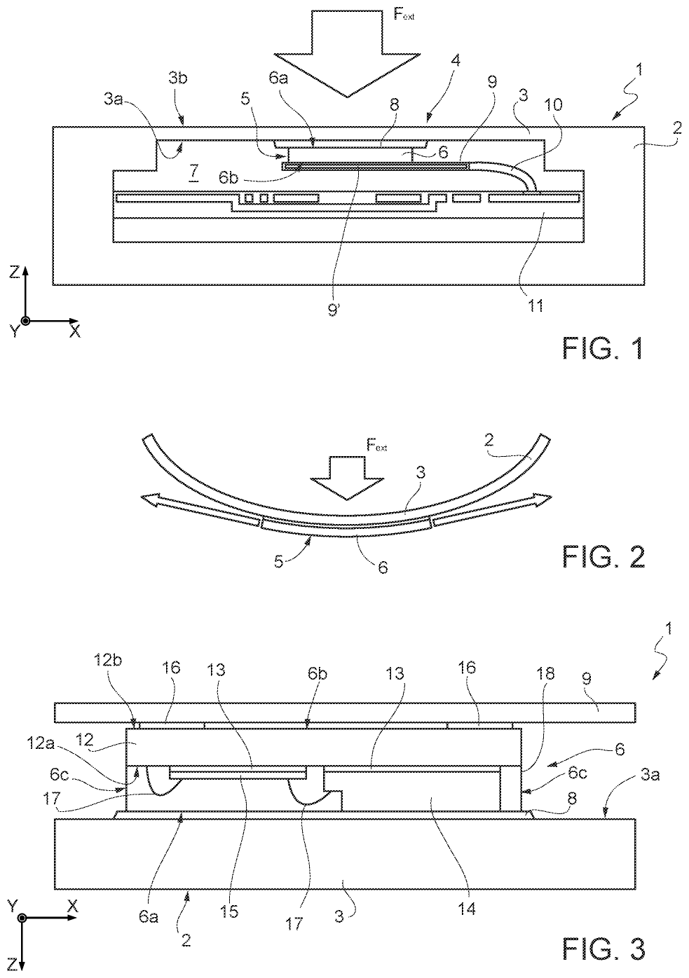

FIG. 1 is a schematic cross-sectional view of a portion of an electronic apparatus 1 of a portable type, for example a smartphone, or of a wearable type, for example a smartwatch.

The electronic apparatus 1 is provided with a case 2, which has a deformable portion 3, which is designed to form part of a user interface element 4, in particular defining a physical button. The aforesaid deformable portion 3 is provided, for example, by thinning (as illustrated in FIG. 1), or other appropriate machining operation, of the aforesaid case 2 so as to define a membrane portion.

According to an aspect of the present solution, the user interface element 4 comprises, in a chamber 7 arranged within the case 2, a microelectromechanical (MEMS) button device 5, having a package 6 coupled to the aforesaid deformable portion 3.

In particular, the package 6 has a first main surface (for example, a top surface) 6a, which extends in a horizontal plane xy and is coupled to an inner surface 3a of the deformable portion 3 facing the chamber 7 inside the case 2, being fixed to the same deformable portion 3, for example by means of an adhesive layer 8 of glue or DAF (Die-Attach Film).

The package 6 further has a second main surface (in the example, a bottom surface) 6b, opposite to the first main surface 6a along a vertical axis z orthogonal to the horizontal plane xy. This second main surface 6b is coupled, inside the aforesaid chamber 7, to a flexible support 9 (for example, a PCB—Printed Circuit Board—of a flexible type.

The above flexible support 9, which integrates appropriate electrical-connection paths 9′ (represented schematically), is in turn electrically connected, by a suitable connection element 10 (for example, including electrical wires and/or an appropriate electrical connector), to a printed circuit board 11, housed within the chamber 7 and fixed to the case 2, to which further circuit elements or components of the aforesaid electronic apparatus 1 may be connected (in a per se evident manner, here not described in detail). Conveniently, also this printed circuit board 11 may be made of flexible material.

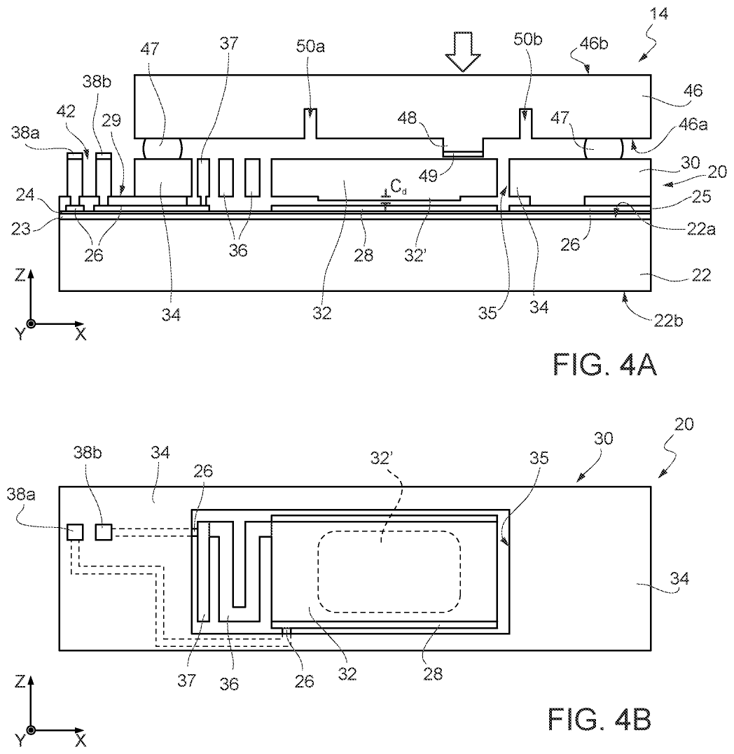

As represented schematically also in FIG. 2, during operation, a pressure (or external force Fₑₓₜ) exerted by the user on the aforesaid deformable portion 3 of the case 2 causes deformation thereof (in particular, bending or deflection towards the chamber 7), which in turn causes a deformation of the package 6 of the microelectromechanical button device 5, fixedly coupled to the same deformable portion 3.

As will be described in detail hereinafter, the deformation experienced by the package 6 of the microelectromechanical button device 5 causes a variation of an electrical output signal supplied by the same microelectromechanical button device 5, this variation in particular being indicative of the state, either open or closed (or likewise pressed or not pressed), of the microelectromechanical button device 5, or, in other words, of the actuation of the same microelectromechanical button device 5.

In particular, according to an embodiment (which will be described in detail), the aforesaid deformation causes a capacitive variation in a detection structure of the microelectromechanical button device 5.

Advantageously, the aforesaid user interface element 4 is intrinsically hermetic, the microelectromechanical button device 5 being in fact arranged within the chamber 7 formed in the case 2 of the electronic apparatus 1, without any access towards the environment external to the electronic apparatus 1.

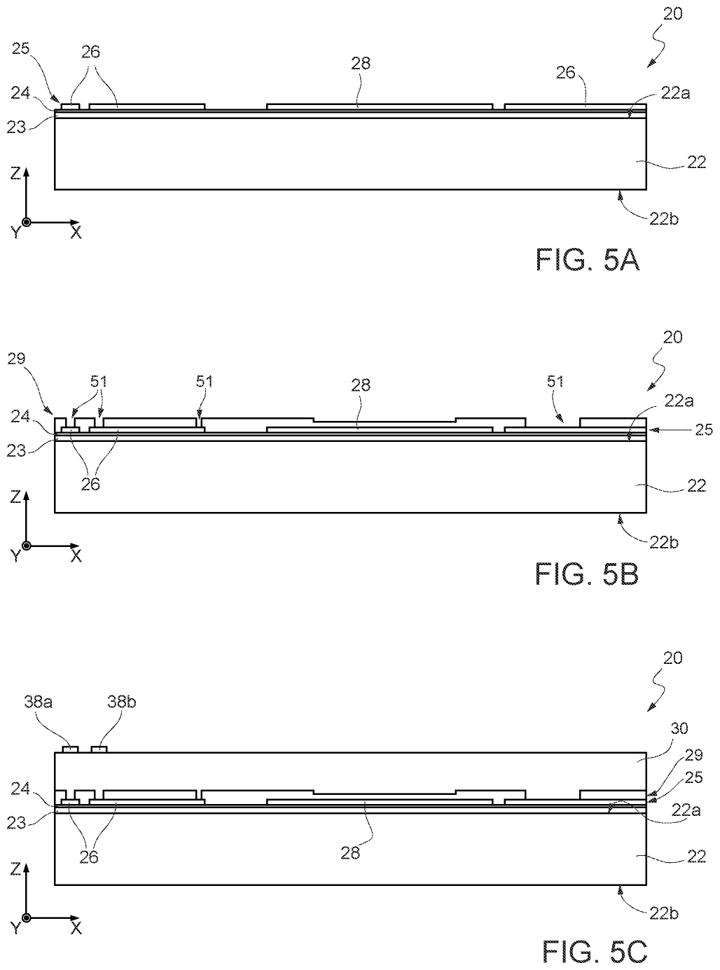

In greater detail, and with reference to FIG. 3, in a possible embodiment, the package 6 of the microelectromechanical button device 5 is of the so-called wafer-level-package type.

The package 6 comprises a base or supporting layer 12, having a front surface 12a; the detection structure, here designated by 14, and an associated electronic circuit 15, of an ASIC (Application-Specific Integrated Circuit) type, provided in respective dies of semiconductor material, are coupled to this supporting layer 12 alongside one another, in particular by means of a respective coupling layer 13.

The supporting layer 12 further has a rear surface 12b, vertically opposite to the front surface 12a, which defines the second main surface 6b of the package 6, which is to be coupled to the flexible support 9, by appropriate electrical-connection elements 16, such as pads, as in the example illustrated in the aforesaid FIG. 3, or conductive bumps.

Electrical wires 17 electrically connect together the detection structure 14 and the associated electronic circuit 15 (in particular, connecting together corresponding contact pads, here not illustrated, carried by a corresponding surface, opposite to the surface of coupling to the supporting layer 12), and also the same electronic circuit 15 to through connection elements (not illustrated) that traverse the supporting layer 12 and reach the electrical-connection elements 16.

A coating 18, for example of epoxy resin, covers and laterally coats the detection structure 14 and the associated electronic circuit 15, further defining part of lateral outer surfaces 6c and of the first main surface 6a of the package 6 (part of the first main surface 6a itself being defined by the surface of the die of the detection structure 14, opposite to the surface of coupling to the supporting layer 12).

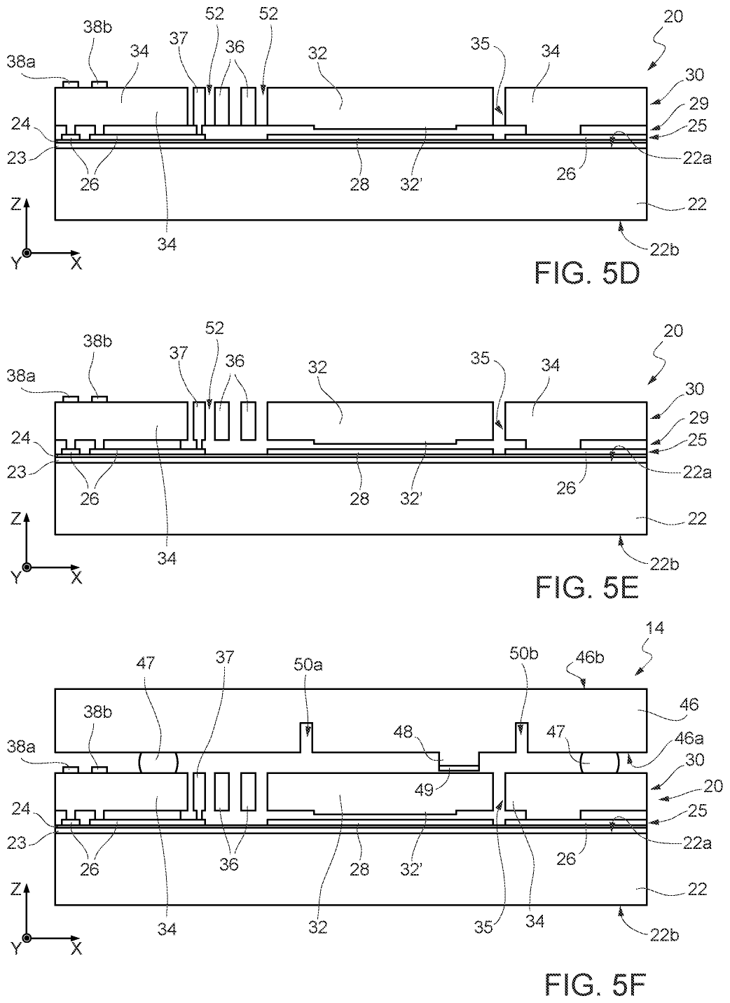

In greater detail, with reference now to FIGS. 4A and 4B the aforesaid detection structure 14 of the microelectromechanical button device 5 is provided in a respective die 20 of semiconductor material, in particular silicon, comprising a substrate 22.

The substrate 22 has a front surface 22a and a rear surface 22b, the latter being designed to be coupled to the aforesaid supporting layer 12 of the package 6 of the microelectromechanical button device 5 (in a way here not illustrated and as represented in FIG. 3).

On the front surface 22a, the detection structure 14 comprises a thermal-oxide layer 23, laid evenly on the same front surface 22a, and a dielectric layer 24, made for example of aluminum oxide or aluminum oxynitride, laid evenly on the aforesaid thermal-oxide layer 23; for reasons that will be clarified hereinafter, the dielectric layer 24 has characteristics of chemical etching selectivity with respect to the aforesaid thermal-oxide layer 23.

The detection structure 14 further comprises, on the aforesaid dielectric layer 24, a conductive layer 25, made for example of polysilicon, appropriately patterned to define, separated from one another by openings, conductive pads or paths, designated as a whole by 26, and, in particular, a buried electrode 28, which, as will on the other hand be clarified hereinafter, is designed to form a first plate of a detection capacitor Cd (represented schematically just in FIG. 4A), with plane and parallel plates, designed to provide an indication of the deformation of the package 6 (and of the operating state, pressed or not pressed, of the microelectromechanical button device 5).

In this embodiment, the buried electrode 28 is fixed, being rigidly coupled to the substrate 22 (via underlying portions of the aforesaid thermal-oxide layer 23 and dielectric layer 24).

The detection structure 14 further comprises a structural layer 30, in particular an epitaxial-silicon layer, formed on the aforesaid conductive layer 25.

The above structural layer 30 is defined and appropriately patterned to form a mobile electrode 32, suspended at a distance over the buried electrode 28, which is designed to form a second plate of the aforesaid detection capacitor Ca (as will be discussed hereinafter, definition of the aforesaid mobile electrode 32 envisages release of part of the structural layer 30 via etching and removal of part of a sacrificial oxide layer 29, formed on the conductive layer 25).

In particular, in the embodiment illustrated in FIGS. 4A and 4B, the aforesaid mobile electrode 32 has a substantially rectangular shape in the horizontal plane xy, with a greater extension along a first horizontal axis x and a smaller extension along a second horizontal axis y (which defines with the first horizontal axis x the aforesaid horizontal plane xy); the mobile electrode 32 further has an active part 32′ projecting at the center in a vertical direction (along the vertical axis z) that faces the buried electrode 28, at a shorter distance therefrom so as to define the aforesaid capacitive coupling. The buried electrode 28 itself has a rectangular shape in the horizontal plane xy, with an extension equal to or greater than the corresponding extension of the mobile electrode 32.

The structural layer 30 is further defined so as to form: an external frame 34, which in the embodiment illustrated has a rectangular ring shape that internally defines a window 35 in which the mobile electrode 32 is located; and an elastic suspension element 36, which in the example has a folded or serpentine conformation.

In detail, the aforesaid elastic suspension element 36 has a first end coupled to the mobile electrode 32, on a first short side of the same mobile electrode 32, and a second end fixedly coupled to the substrate 22.

In the example illustrated, the above second end is connected to an anchorage element 37 formed starting from the aforesaid structural layer 30 and coupled underneath to one of the aforesaid conductive pads or paths 26 formed on the substrate 22.

In a way not illustrated, it is, however, pointed out that the second end of the elastic suspension element 36 could alternatively be coupled to a facing side of the external frame 34.

The mobile electrode 32 is in any case suspended in cantilever fashion over the buried electrode 28, and the aforesaid elastic suspension element 36 enables deflection thereof in the direction of the vertical axis z, towards the underlying buried electrode 28.

The detection structure 14 further comprises, on the structural layer 30, outside the external frame 34, a first contact pad 38a and a second contact pad 38b, which are made of metal material.

The above first and second contact pads 38a, 38b are electrically coupled to respective conductive pads or paths 26 formed in the aforesaid conductive layer 25, through a respective portion of the structural layer 30, said portions of the structural layer 30 being separated from one another and being further separated from the external frame 34 by respective openings 42 provided through the same structural layer 30.

In particular, the first and second contact pads 38a, 38b are electrically coupled, respectively, to the buried electrode 28 and to the mobile electrode 32 by a first conductive path and a second conductive path, respectively. The first conductive path comprises a respective portion of the structural layer 30, a respective conductive pad or path 26, the anchorage element 37, and the elastic suspension element 36; the second conductive path comprises a respective portion of the structural layer 30 and a respective conductive pad or path 26, which reaches the aforesaid buried electrode 28.

The detection structure 14 further comprises a cap 46, of deformable material, in particular deformable silicon, arranged above the aforesaid structural layer 30, to which it is coupled by bonding regions 47, for example in the form of bumps of an appropriate bonding material.

The above cap 46 has a first main surface 46a facing the structural layer 30 and a second main surface 46b, which is vertically opposite to the first main surface 46a and defines part of the aforesaid first main surface 6a of the package 6 (see also FIG. 3).

In particular, the aforesaid cap 46 has an actuation projection 48, which extends vertically from the first main surface 46a towards the structural layer 30, has, for example, a square or rectangular shape in the horizontal plane xy, and has one end 49 coated by thermal oxide, arranged in contact with or in strict proximity to the mobile electrode 32, in the example in a position corresponding to the second short side, opposite to the first short side coupled to the elastic suspension element 36.

The cap 46 further has, on opposite sides of the aforesaid actuation portion 48 along the first horizontal axis x, a first recess 50a and a second recess 50b that extend from the first main surface 46a towards the inside of the same cap 46, in a vertical direction (along the vertical axis z) for example approximately for one half of the thickness of the cap 46. In the example illustrated, these first and second recesses 50a, 50b are arranged vertically at the first short side and, respectively, at the second short side of the mobile electrode 32.

As illustrated schematically in the above FIG. 4A, the pressure applied to the cap 46 on the actuation portion 48 (corresponding to the external force Fₑₓₜ applied on the case 2 of the electronic apparatus 1 at the user interface element 4) causes a deflection of the mobile electrode 32 and its approach to the buried electrode 28, with a consequent capacitive variation of the detection capacitor Cd.

The above capacitive variation may be acquired and processed, for example by the electronic circuit 15 within the package 6 of the microelectromechanical button device 5.

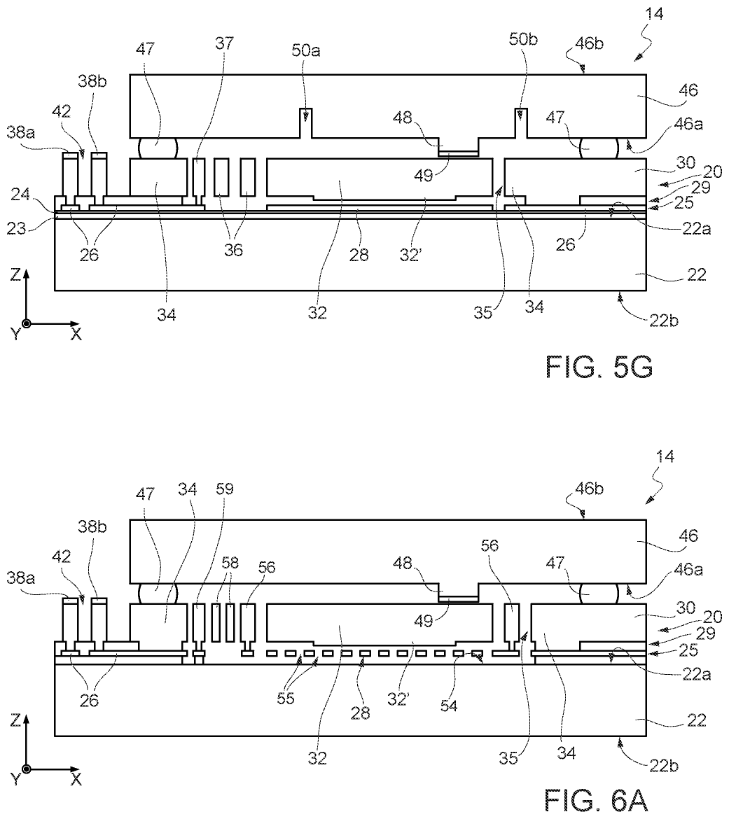

With reference first to FIG. 5A, the process for manufacturing of the aforesaid detection structure 14 is now described; this process envisages first formation of the thermal-oxide layer 23 by oxidation of the front surface 22a of the substrate 22 and then formation of the dielectric layer 24 on the thermal-oxide layer 23 (the thermal-oxide layer 23 and the dielectric layer 24 forming together a combined layer of permanent-dielectric).

Then, as shown in FIG. 5A, the conductive layer 25 is formed on the aforesaid dielectric layer 24, made, for example, of polysilicon; the same conductive layer 25 is then defined and patterned by an appropriate photolithographic mask, to form the conductive pads or paths 26 and the buried electrode 28.

Next (FIG. 5B), the sacrificial oxide layer 29 is formed on the conductive layer 25 and is then defined and patterned by a respective photolithographic mask, to form openings 51, which are to enable access to respective conductive pads or paths 26 previously defined.

Next (FIG. 5c), epitaxial growth is carried out to form the structural layer 30 on the aforesaid sacrificial oxide layer 29, followed by an appropriate step of CMP (Chemical Mechanical Polishing) of a corresponding top surface.

As shown in the same FIG. 5C, the first and second contact pads 38a, 38b are then formed by deposition and etching of a layer of metal material on the structural layer 30.

A step of etching of the aforesaid structural layer 30 is then carried out (FIG. 5D) to form trenches 52 (in FIG. 5D some of these trenches are represented by way of example) throughout the thickness of the structural layer 30, which enable access to the underlying sacrificial oxide layer 29. These trenches 52 further define the shape of the elements formed in the structural layer 30, which in particular comprise the mobile electrode 32, the external frame 34, the elastic suspension element 36, and the anchorage element 37.

As shown in FIG. 5E, a chemical etching is then carried out, for example using hydrofluoric acid (HF), of the aforesaid sacrificial oxide layer 29 through the trenches 52. This etching stops on the dielectric layer 24 and leads to release of the mobile electrode 32 and of the associated elastic suspension element 36, which thus remain suspended above the underlying substrate 22, at a certain distance from the underlying conductive layer 25.

The process then continues (FIG. 5F) with bonding, on the structural layer 30, of the cap 46 by the bonding regions 47 (the cap 46 itself having previously been machined to form the actuation portion 48 and the first and second recesses 50a, 50b).

As shown in FIG. 5G, the above cap 46 is then appropriately patterned by an etching step, so as to make the underlying first and second contact pads 38a, 38b on the structural layer 30 accessible and further enable formation of the openings 42 through the same structural layer 30.

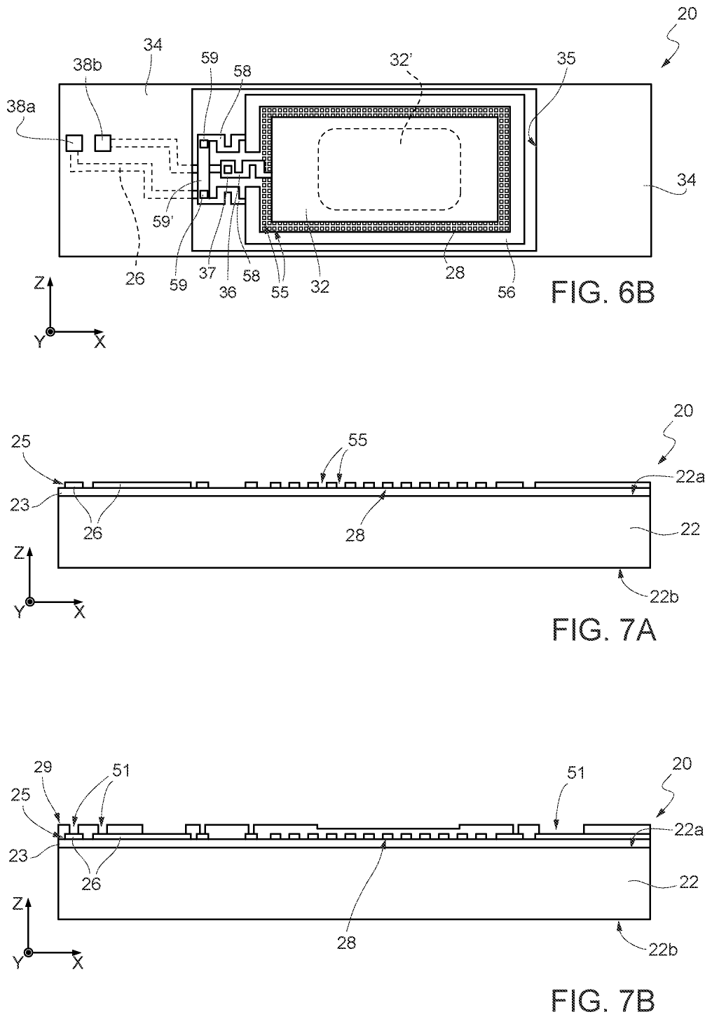

A description of a further embodiment of the detection structure 14 is now presented, with reference to FIGS. 6A and 6B; this embodiment envisages that also the buried electrode 28, just as the mobile electrode 32, is elastically decoupled from the substrate 22 of the die 20.

In detail, in this embodiment, the buried electrode 28, once again formed starting from the conductive layer 25, is suspended at a distance above the top surface 22a of the substrate 22, a buried cavity 54 being present between the top surface 22a and the same buried electrode 28. It should be noted that a plurality of openings 55 are formed through the buried electrode 28 in a vertical direction. These openings 55 facilitate, as on the other hand will be highlighted hereinafter, removal of sacrificial material for the formation of the aforesaid buried cavity 54 underneath the same buried electrode 28.

The buried electrode 28 is supported in its position suspended above the buried cavity 54 by an overlying inner frame 56, formed starting from the structural layer 30 (as likewise are the mobile electrode 32 and the external frame 34). In particular, coupling between the buried electrode 28 and the aforesaid inner frame 56 is provided at the periphery or edge of the same buried electrode 28.

In the embodiment illustrated in FIG. 6B, the buried electrode 28 has a substantially rectangular shape in the horizontal plane xy, with a greater extension than the corresponding extension of the mobile electrode 32 in the same horizontal plane xy; in other words, the inner frame 56 externally surrounds the mobile electrode 32.

The aforesaid inner frame 56 is elastically decoupled from the substrate 22 by respective elastic suspension elements 58, in the example illustrated having a folded shape and an extension along the first horizontal axis x of the horizontal plane xy, on opposite sides of the aforesaid elastic suspension element 36 with respect to the second horizontal axis y.

In detail, the above elastic suspension elements 58 have a respective first end coupled to the inner frame 56 and a respective second end fixedly coupled to the substrate 22.

In the example illustrated, the above second end is connected to a respective anchorage element 59 formed starting from the aforesaid structural layer 30 and coupled underneath to one of the aforesaid conductive paths 26 formed on the substrate 22. In the same example, the above anchorage elements 59 are further coupled together by a connection element 59′, which is also formed in the structural layer 30 and has an extension along the second horizontal axis y.

In a way not shown, it is, however, pointed out that just one elastic suspension element 58 coupled to the inner frame 56 could alternatively be provided. Furthermore, the second end of the aforesaid elastic suspension element 58 could be coupled to a facing side of the external frame 34, for example arranged on an opposite side with respect to the side of the external frame 34 coupled to the anchorage element 37 of the elastic suspension element 36.

Advantageously, in this embodiment, elastic decoupling of the buried electrode 28 from the substrate 22 allows the performance of the detection structure 14 not to be affected by possible deformation of the same substrate 22, for example due to thermal stresses or ageing phenomena.

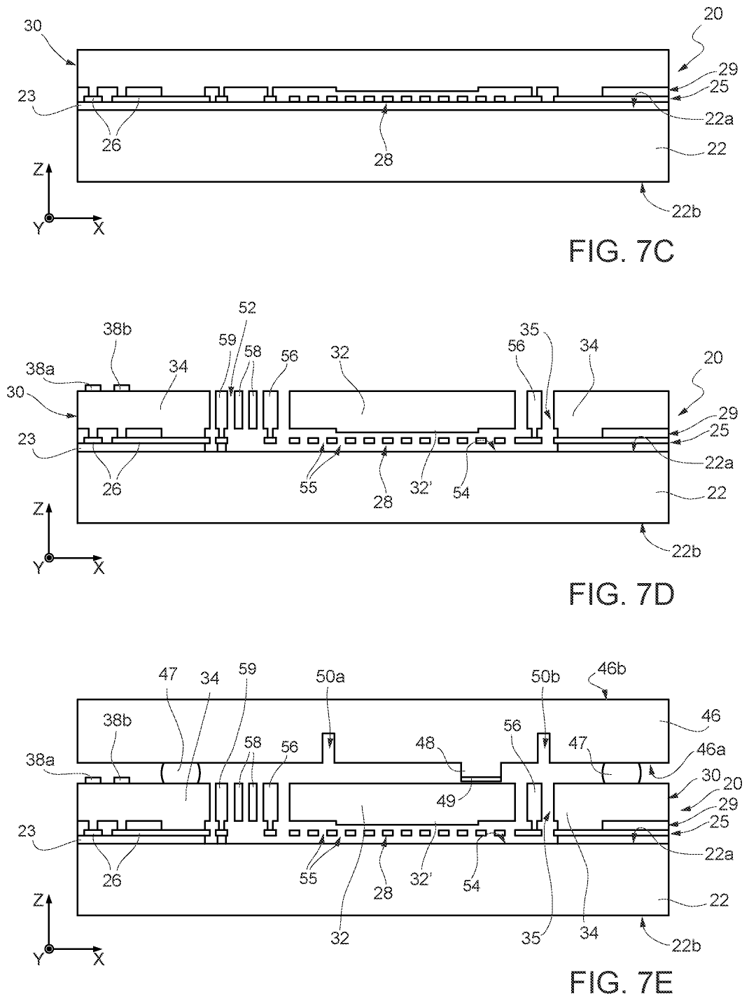

With initial reference to FIG. 7A, a description of the process for manufacturing the aforesaid detection structure 14 is now presented, in relation to the further embodiment just described.

The above process envisages also in this case formation of the thermal-oxide layer 23 by oxidation of the front surface 22a of the substrate 22. In this case, instead, the dielectric layer 24 is not formed on the thermal-oxide layer 23, but rather directly the conductive layer 25, made, for example, of polysilicon, which is defined and patterned by an appropriate photolithographic mask to form the conductive pads or paths 26 and the buried electrode 28. It should be noted that this step of photolithographic etching leads also to definition of the openings 55 through the buried electrode 28.

Next (FIG. 7B), 5 the sacrificial oxide layer 29 is formed on the conductive layer 2 and is then defined and patterned by the respective photolithographic mask. In particular, in this case, the sacrificial oxide layer 29 enters and fills the aforesaid openings 55.

Next (FIG. 7c), epitaxial growth is carried out to form the structural layer 30 on the aforesaid sacrificial oxide layer 29.

As shown in FIG. 7D, the first and second contact pads 38a, 38b are then formed on the structural layer 30. The step of etching of the aforesaid structural layer 30 is then carried out to form the trenches 52 throughout the thickness of the same structural layer 30, enabling access to the underlying sacrificial oxide layer 29.

The above trenches 52 further define the elements formed in the structural layer 30, in particular the mobile electrode 32, the external frame 34, the inner frame 56, the elastic suspension elements 36 and 58 and the anchorage elements 37, 59 (the cross-sectional view of FIG. 7D showing the elastic suspension element 58 and the corresponding anchorage element 59).

As shown once again in FIG. 7D, chemical etching, for example using hydrofluoric acid (HF), of the aforesaid sacrificial oxide layer 29 is then carried out through the trenches 52. Etching stops in this case on the front surface 22a of the substrate 22 and leads to release of the mobile electrode 32 and, in this case, also of the buried electrode 28 (as well as of the external and inner frames 34, 56 and of the elastic suspension elements 36, 58).

The process then continues, as described previously (FIG. 7E) with coupling of the cap 46 on the structural layer 30, by the bonding regions 47, and further (FIG. 7F) with machining of the cap 46 itself so as to make the underlying first and second contact pads 38a, 38b accessible and to further enable formation of the openings 42 through the structural layer 30.

The advantages of the present solution are clear from the foregoing description.

In any case, it is once again pointed out that the solution described enables provision of a user interface element for an electronic apparatus, in particular of a portable or wearable type, which is intrinsically waterproof and has several advantages over traditional solutions, amongst which: a reduced energy consumption, low costs, and low complexity of manufacturing, high yield, accuracy, and speed in detection.

Finally, it is clear that modifications and variations may be made to what has been described and illustrated herein, without thereby departing from the scope of the present disclosure.

For instance, it is pointed out that the first and second recesses 50a, 50b might not be provided in the cap 46 at the sides of the actuation portion 48.

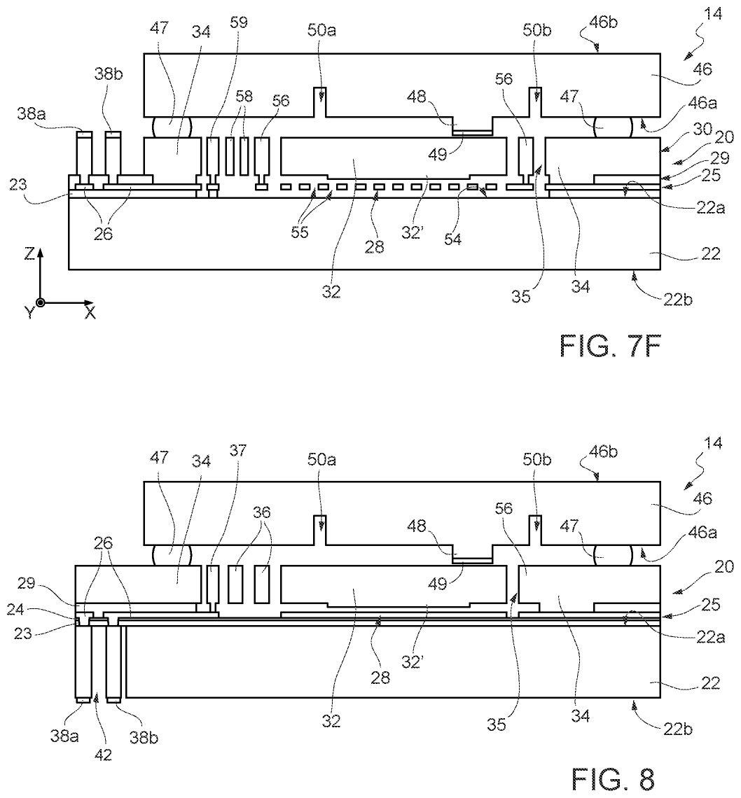

Furthermore, as shown in FIG. 8, a possible alternative embodiment may envisage formation of the first and second contact pads 38a, 38b on the back of the substrate 22, on the corresponding rear surface 22b.

In this case, the respective pads 26 formed in the conductive layer 25 extend through the underlying dielectric layer 24 and thermal-oxide layer 23 to reach respective portions of the substrate 22, which extend vertically throughout its thickness, separated by the openings 42, which in this case are obtained as trenches through the same substrate 22.

In a possible embodiment, the package 6 of the microelectromechanical button device 5 may further comprise just the detection structure 14 and not the associated electronic circuit 15. In this case, the functions of driving of the buried and mobile electrodes 28, 32 and of processing of the capacitive variation of the detection capacitor C d may be carried out by an electronic circuitry external to the microelectromechanical button device 5, for example coupled to the PCB 10.

Furthermore, it is highlighted that it is possible to implement a detection in a resonance condition of the capacitive variation of the detection capacitor C d formed between the mobile electrode 32 and the buried electrode 28 of the detection structure 14.

A microelectromechanical button device (5) may be summarized as including a detection structure (14) having: a substrate (22) of semiconductor material with a front surface (22a) and a rear surface (22b), which have an extension in a horizontal plane (xy) and are opposite to one another along a vertical axis (z), orthogonal to the horizontal plane (xy); a buried electrode (28) arranged on the substrate (22); a mobile electrode (32), arranged in a structural layer (30) overlying the substrate (22) and elastically suspended above the buried electrode (28) at a separation distance so as to form a detection capacitor (Ca); and a cap (46) coupled over the structural layer (30) and having a first main surface (46a) facing the structural layer (30) and a second main surface (46b), opposite to the first main surface (46a) along the vertical axis (z), which is designed to be mechanically coupled to a deformable portion (3) of a case (2) of an electronic apparatus (1) of a portable or wearable type, wherein said cap (46) has, on said first main surface (46a), an actuation portion (48) arranged on the mobile electrode (32) and configured so as to cause, in the presence of a pressure applied on the second main surface (46b), a deflection of the mobile electrode (32) and its approach to the buried electrode (28), with a consequent capacitive variation of the detection capacitor (Ca), said capacitive variation being indicative of an actuation of said microelectromechanical button device (5).

The pressure may be the result of a deformation of the deformable portion (3) of the case (2) of the electronic apparatus (1), due to an external force (Fₑₓₜ) applied on said deformable portion (3) from outside of said case (2) for actuation of said microelectromechanical button device (5).

The cap (46) may have, on opposite sides of the aforesaid actuation portion (48), a first recess (50a) and a second recess (50b), which extend within the cap (46), in the direction of the vertical axis (z).

The actuation portion (48) may be a projection, which extends along the vertical axis (z) starting from the first main surface (46a) of the cap (46) towards the structural layer (30) and has one end (49) arranged in contact with, or in strict proximity of, the mobile electrode (32).

The detection structure (14) may further include an elastic suspension element (36), arranged in said structural layer (30) and having a first end coupled to the mobile electrode (32) and a second end fixedly coupled to the substrate (22), said elastic suspension element (36) being configured to support said mobile electrode (32) suspended in cantilever fashion above the buried electrode (28) and to enable deflection thereof towards the underlying buried electrode (28).

The second end may be connected to an anchorage element (34, 37) arranged in the structural layer (30) and fixedly coupled to said substrate (22) by a conductive element (26), configured for electrical connection to said mobile electrode (32).

The detection structure (14) may further include an external frame (34) formed in said structural layer (30) and internally defining a window (35) wherein the mobile electrode (32) is arranged; said cap (46) being coupled to said external frame (34) by bonding regions (47).

The anchorage element may be defined by a portion of said external frame (34).

The buried electrode (28) may be suspended at a distance above the top surface (22a) of the substrate (22), a buried cavity (54) being arranged between said top surface (22a) and said buried electrode (28).

The buried electrode (28) may be supported in its position suspended above the buried cavity (54) by an overlying inner frame (56), arranged in the structural layer (30); wherein said inner frame (56) is elastically decoupled from said substrate (22) by at least one respective elastic suspension element (58) having a respective first end coupled to the inner frame (56) and a second end fixedly coupled to the substrate (22).

The second end of said respective elastic suspension element (58) may be connected to a respective anchorage element (59) arranged in the structural layer (30) and fixedly coupled to said substrate (22) by a respective conductive element (26), configured for electrical connection to said buried electrode (28).

The device may further include a package (6) having a supporting layer (12), with a respective front surface (12a), to which said detection structure (14) is coupled, and a respective rear surface (12b), opposite to the respective front surface (12a), which defines a main outer surface (6b) of the package (6), which is designed to be coupled to a flexible support (9) integrating electrical-connection paths (9′) and housed within the case (2) of said electronic apparatus (1); said package (6) may further include a coating (18) that covers and coats laterally the detection structure (14) to define part of outer lateral surfaces (6c) and part of a further main outer surface (6a) of the package (6), part of said further main outer surface (6a) being defined by the second main surface (46b) of the cap (46) of said detection structure (14).

The device may further include an electronic circuit (15), associated with the detection structure (14), provided in a respective die of semiconductor material, coupled to said supporting layer (12) arranged alongside said detection structure (14).

A user interface element (4) for a portable or wearable electronic apparatus (1) may be summarized as including: the microelectromechanical button device (5) according to any one of the embodiments discussed above; and, moreover, said deformable portion (3) of said case (2) of the electronic apparatus (1).

A portable or wearable electronic apparatus (1) may be summarized as including the user interface element (4) as discussed above, which defines a physical button.

The electronic apparatus may include: a chamber (7) inside the case (2), in which said microelectromechanical button device (5) is arranged; a flexible support (9) integrating electrical-connection paths (9′) housed within the chamber (7) and to which said microelectromechanical button device (5) is electrically and mechanically coupled; and a printed-circuit board (11), housed within the chamber (7) and fixed to the case (2); wherein said flexible support (9) is coupled to said printed-circuit board (11) by a connection element (10).

A process for the manufacturing of a microelectromechanical button device (5) may be summarized as including: providing a substrate (22) of semiconductor material having a front surface (22a) and a rear surface (22b), which have an extension in a horizontal plane (xy) and are opposite to one another along a vertical axis (z), orthogonal to the horizontal plane (xy); forming a buried electrode (28), via definition of a conductive layer (25) on the substrate (22); forming a mobile electrode (32), via definition of a structural layer (30) overlying the substrate (22), elastically suspended above the buried electrode (28) at a separation distance so as to form a detection capacitor (C d); and coupling a cap (46) on the structural layer (30), having a first main surface (46a) that faces the structural layer (30) and a second main surface (46b), opposite to the first main surface (46a) along the vertical axis (z), that is designed to be mechanically coupled to a deformable portion (3) of a case (2) of an electronic apparatus (1) of a portable or wearable type; forming an actuation portion (48) of said cap (46), at said first main surface (46a), said actuation portion (48) being arranged over the mobile electrode (32) and being configured to cause, in the presence of a pressure applied on the second main surface (46b), a deflection of the mobile electrode (32) and its approach to the buried electrode (28), with a consequent capacitive variation of the detection capacitor (C d), said capacitive variation being indicative of an actuation of said microelectromechanical button device (5).

The process may further include forming an elastic suspension element (36), via definition of said structural layer (30), having a first end coupled to the mobile electrode (32) and a second end fixedly coupled to the substrate (22), said elastic suspension element (36) being configured to support said mobile electrode (32) suspended in cantilever fashion above the buried electrode (28) and to enable deflection thereof towards the underlying buried electrode (28).

Forming said buried electrode (28) may include forming said buried electrode (28) suspended at a distance above the top surface (22a) of the substrate (22), a buried cavity (54) being arranged between said top surface (22a) and said buried electrode (28); forming, via definition of said structural layer (30): an inner frame (56), which supports, in its position suspended above the buried cavity (54), the underlying buried electrode (28); and a respective elastic suspension element (58), which has a respective first end coupled to the inner frame (56) and a second end fixedly coupled to the substrate (22).

The process may further include forming a first recess (50a) and a second recess (50b), which extend within the cap (46), in the direction of the vertical axis (z), on opposite sides of said actuation portion (48).

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A microelectromechanical button device, comprising:
a substrate of semiconductor material with a front surface and a rear surface, which have an extension in a horizontal plane and are opposite to one another along a vertical axis, orthogonal to the horizontal plane;
a buried electrode on the substrate;
a structural layer including a mobile electrode overlying the substrate and elastically suspended above the buried electrode at a separation distance so as to form a detection capacitor; and
a cap coupled to the structural layer and having a first main surface facing the structural layer and a second main surface opposite to the first main surface along the vertical axis, is the cap being designed to be mechanically coupled to a deformable portion of a case of an electronic apparatus,
wherein the cap has, on the first main surface, an actuation portion on the mobile electrode and configured so as to cause, in the presence of a pressure applied on the second main surface, a deflection of the mobile electrode towards the buried electrode, the deflection configured to cause a capacitive variation of the detection capacitor, the capacitive variation being indicative of an actuation of the microelectromechanical button device.

2. The microelectromechanical button device according to claim 1, wherein the pressure is the result of a deformation of the deformable portion of the case of the electronic apparatus, due to an external force applied on the deformable portion from outside of the case for actuation of the microelectromechanical button device.

3. The microelectromechanical button device according to claim 1, wherein the cap has, on opposite sides of the actuation portion, a first recess and a second recess, which extend into the cap in a direction of the vertical axis.

4. The microelectromechanical button device according to claim 1, wherein
the actuation portion is a projection, which extends along the vertical axis starting from the first main surface of the cap towards the structural layer, and
the actuation portion has one end arranged in contact with or in proximity of the mobile electrode.

5. The microelectromechanical button device according to claim 1, wherein the structural layer includes an elastic suspension element having a first end coupled to the mobile electrode and a second end fixedly coupled to the substrate, the elastic suspension element being configured to support the mobile electrode suspended in cantilever fashion above the buried electrode and to enable deflection of the mobile electrode towards the buried electrode.

6. The microelectromechanical button device according to claim 5, further comprising:
a conductive element on the substrate,
wherein the structural layer includes an anchorage element fixedly coupled to the substrate by the conductive element, the conductive element configured for electrical connection to the mobile electrode.

7. The microelectromechanical button device according to claim 6, wherein the structural layer includes an external frame that internally defines a window in which the mobile electrode is arranged, the cap being coupled to the external frame by bonding regions.

8. The microelectromechanical button device according to claim 7, wherein the anchorage element is defined by a portion of the external frame.

9. The microelectromechanical button device according to claim 1, further comprising:
a buried cavity being arranged between the front surface and the buried electrode, the buried electrode being suspended at a distance above the front surface of the substrate.

10. The microelectromechanical button device according to claim 9, further comprising:
an inner frame arranged in the structural layer, the buried electrode being supported in its position suspended above the buried cavity by the inner frame,
wherein the inner frame is elastically decoupled from the substrate by at least one respective elastic suspension element having a respective first end coupled to the inner frame and a second end fixedly coupled to the substrate.

11. The microelectromechanical button device according to claim 10, further comprising:
a respective conductive element,
wherein the structural layer includes a respective anchorage element, and
the second end of the respective elastic suspension element is connected to the respective anchorage element and fixedly coupled to the substrate by the respective conductive element, the respective conductive element configured for electrical connection to the buried electrode.

12. The microelectromechanical button device according to claim 1, further comprising:
a detection structure including the substrate, the buried electrode, the structural layer, and the cap; and
a package having a supporting layer with a respective front surface, to which the detection structure is coupled, and a respective rear surface, opposite to the respective front surface,
wherein the respective rear surface defines a main outer surface of the package, the package configured to be coupled to a flexible support integrating electrical-connection paths and housed within the case of the electronic apparatus, and
the package includes a coating that covers and coats laterally the detection structure to define part of outer lateral surfaces and part of a further main outer surface of the package, part of the further main outer surface being defined by the second main surface of the cap of the detection structure.

13. The microelectromechanical button device according to claim 12, further comprising:
an electronic circuit associated with the detection structure and in a respective die of semiconductor material, coupled to the supporting layer alongside the detection structure.

14. A user interface element, comprising:
a case having a deformable portion; and
a microelectromechanical button device including:
a substrate of semiconductor material with a front surface and a rear surface, which have an extension in a horizontal plane and are opposite to one another along a vertical axis, orthogonal to the horizontal plane;
a buried electrode on the substrate;
a structural layer including a mobile electrode overlying the substrate and elastically suspended above the buried electrode at a separation distance so as to form a detection capacitor; and
a cap coupled to the structural layer and having a first main surface facing the structural layer and a second main surface opposite to the first main surface along the vertical axis, is the cap being designed to be mechanically coupled to the deformable portion of the case,
wherein the cap has, on the first main surface, an actuation portion on the mobile electrode and configured so as to cause, in the presence of a pressure applied on the second main surface, a deflection of the mobile electrode towards the buried electrode, the deflection configured to cause a capacitive variation of the detection capacitor, the capacitive variation being indicative of an actuation of the microelectromechanical button device.

15. The user interface element of claim 14 wherein the user interface element defines a physical button.

16. An electronic apparatus, comprising:
a case having a deformable portion; and
a user interface element that defines a physical button, the user interface element having a microelectromechanical button device including:
a substrate of semiconductor material with a front surface and a rear surface, which have an extension in a horizontal plane and are opposite to one another along a vertical axis, orthogonal to the horizontal plane;
a buried electrode on the substrate;
a structural layer including a mobile electrode overlying the substrate and elastically suspended above the buried electrode at a separation distance so as to form a detection capacitor; and
a cap coupled to the structural layer and having a first main surface facing the structural layer and a second main surface opposite to the first main surface along the vertical axis, is the cap being designed to be mechanically coupled to the deformable portion of the case,
wherein the cap has, on the first main surface, an actuation portion on the mobile electrode and configured so as to cause, in the presence of a pressure applied on the second main surface, a deflection of the mobile electrode towards the buried electrode, the deflection configured to cause a capacitive variation of the detection capacitor, the capacitive variation being indicative of an actuation of the microelectromechanical button device.

17. The electronic apparatus according to claim 16, further comprising:
a chamber inside the case, the microelectromechanical button device being arranged in the chamber;
a flexible support integrating electrical-connection paths housed within the chamber, the microelectromechanical button device being electrically and mechanically coupled to the flexible support; and
a printed-circuit board housed within the chamber and fixed to the case the flexible support being coupled to the printed-circuit board by a connection element.

18. The electronic apparatus according to claim 16, wherein the electronic apparatus is a portable or a wearable electronic apparatus.

19. A process for manufacturing of a microelectromechanical button device, the process comprising:
forming a buried electrode, via definition of a conductive layer, on a substrate of semiconductor material, the substrate having a front surface and a rear surface, which have an extension in a horizontal plane and are opposite to one another along a vertical axis, orthogonal to the horizontal plane;
forming a mobile electrode, via definition of a structural layer, overlying the substrate, and elastically suspended above the buried electrode at a separation distance so as to form a detection capacitor;
coupling a cap to the structural layer, the cap having a first main surface that faces the structural layer and a second main surface, opposite to the first main surface along the vertical axis, the cap being designed to be mechanically coupled to a deformable portion of a case of an electronic apparatus; and
forming an actuation portion of the cap, at the first main surface, the actuation portion being arranged over the mobile electrode and being configured to cause, in the presence of a pressure applied on the second main surface, a deflection of the mobile electrode towards the buried electrode, the deflection configured to cause a capacitive variation of the detection capacitor, the capacitive variation being indicative of an actuation of the microelectromechanical button device.

20. The process according to claim 19, further comprising:
forming an elastic suspension element, via definition of the structural layer, the elastic suspension element having a first end coupled to the mobile electrode and a second end fixedly coupled to the substrate, the elastic suspension element being configured to support the mobile electrode suspended in cantilever fashion above the buried electrode and to enable deflection of the mobile electrode towards the buried electrode.

21. The process according to claim 19, wherein
forming the buried electrode includes forming the buried electrode suspended at a distance above the front surface of the substrate, a buried cavity being arranged between the front surface and the buried electrode,
the process includes:
forming, via definition of the structural layer, an inner frame that supports the buried electrode in its position suspended above the buried cavity; and
forming a respective elastic suspension element, which has a respective first end coupled to the inner frame and a second end fixedly coupled to the substrate.

22. The process according to claim 19, further comprising:
forming a first recess and a second recess, which extend within the cap, in the direction of the vertical axis, on opposite sides of the actuation portion.
